(19) United States
(12) Patent Application Publication
(10) Pub. No.: US 2026/0271195 A1
(43) Pub. Date: Sep. 10, 2026

(54) METHOD AND APPARATUS FOR PRODUCING A METAL HYBRID MATERIAL WITH LEVEL LAYERING OVER A ROUGH BASE SURFACE

(71) Applicant: Atlas Magnetics, Reno, NV (US)

(72) Inventor: John McDonald, Reno, NV (US)

(21) Appl. No.: 19/103,148

(22) PCT Filed: Jul. 11, 2023
(86) PCT No.: PCT/US2023/027416

§ 371 Date: Feb. 11, 2025

(51) Int. Cl. H05K 3/46; H05K 1/03

(52) U.S. Cl. CPC H05K 3/4673; H05K 1/0353

(57) ABSTRACT

The present invention enables higher efficiency, stronger mechanical strength, and smaller realized size in electrical components utilizing hybrid material with porous insulation layers. In at least one exemplary embodiment, a base layer is naturally rough or intentionally roughened, thus reducing the performance of a thin film hybrid material deposited on such a rough surface. The peaks and valleys of the roughened layer will act like joints helping hold the base layer to the subsequent layers. To avoid the negative consequences of contoured current or flux pathways in the primary hybrid layer and to improve the performance of the hybrid material layer, an intermediate layer is utilized. The intermediate layer absorbs the roughness of the base layer and presents a smooth surface for the primary hybrid material layer.

### BACKGROUND

The field of the invention generally relates to circuits, and more specifically, it relates to the use of conductive and magnetic materials within electrical circuits and circuit components.

Many circuit components in the microelectronics industry are created by layering processes. In many cases, a conductive or magnetic material is deposited onto a base layer, for example, a material used to package integrated circuits “IC” or a material used to manufacture printed circuit boards. All surfaces have an average roughness that comprises peaks and valleys. These peaks and valleys will interlock with material deposited onto the base's surface so that the two layers create a mechanical bond. It is often beneficial to start with a naturally rough base layer or intentionally roughen a base layer to improve adhesion with additional material being deposited onto the base layer. For example, sanding or chemically treating the surface could provide a rougher surface which would increase the mechanical bonding between the base and the material deposited onto its surface. It will be appreciated that this mechanical bonding is a positive effect which is increased as the surface roughness of the base is increased, preventing delamination.

However, when depositing material to provide a path for electrical current or magnetic flux, the deposited material follows the contours of the base, and thus the rough base layer's peaks and valleys interfere with the electrical current or magnetic flux path and increase resistance or reluctance of the deposited layer, respectively. This rough path lengthens the pathways compared to a straight path, thus increasing the system's resistance or reluctance respectively. The rougher the base layer surface, the longer the current path will be.

Depositing hybrid materials, which are materials containing layers of porous insulation, onto the base layer may compound the adverse effects. In hybrid materials, created by processes such as combustion chemical vapor deposition (CCVD) or plasma-enhanced vapor deposition, the insulation material may fall like snow, and as a result, the insulation may accumulate in valleys and on peaks. The insulation may also avoid any near-vertical surfaces or areas under overhangs. This uneven distribution of insulation material—hybrid material from reaching its full potential by reducing the protection the material offers against eddy currents-with some areas even potentially offering no insulative protection at all. The hybrid material will also have longer flux or current pathways, and thus the result of depositing hybrid materials onto rough surfaces is to create a longer current pathway with nominal resistance to eddy currents.

Therefore, the compounded adverse effects of forming porous insulation layers by deposition onto rough base layers, for example, semiconductor packaging materials or printed circuit boards, reduce the benefits of the hybrid materials. As the benefits of mechanical bonding are desired, along with a realization of the full potential of the hybrid material, there is a need to provide a means to eliminate or significantly reduce the adverse effects on hybrid material from using rough or roughened base layers.

### BRIEF SUMMARY OF THE PRESENT INVENTION

The present invention reduces or eliminates the negative effects of depositing on rough base layers, for example, semiconductor packaging materials or printed circuit boards, in relation to surface roughness, allowing the surface of a base layer to even be intentionally roughened for increased mechanical bonding. This enables the use of hybrid materials on naturally rough or intentionally roughened semiconductor packaging materials or printed circuit boards and improves the consistency of hybrid material performance.

These benefits are achieved by the creation of an intermediate layer between the base layer and the primary hybrid material layer, which comprises a metal layer having a first rugged surface and a first smooth surface, the first rugged surface operably bonded to a semiconductor packaging material or printed circuit board, and the first smooth surface operably bonded to a hybrid metal. Thus the intermediate layer sits between the base layer and the primary hybrid material layer. The intermediate layer allows the hybrid material itself to have a layer roughness equivalent to the first smooth surface of the intermediate layer as opposed to the base layer.

The result is a rough or roughened base layer surface, an intermediate layer absorbing the roughness of the base layer and presenting a smooth surface for the hybrid material, and a hybrid material resting on the smooth surface of the intermediate layer, which acts as a level plane for the hybrid material.

It will be appreciated that the terms rough and smooth refer to the relative state of a surface with respect to the industry standard term for average roughness, Ra. If the surface has been treated in some manner to produce a surface with less roughness than the initially occurring surface, then the surface is considered smooth. In regards to an intermediary layer, when the Ra of the base layer's upper surface is greater than the Ra of the opposing side of the intermediate layer, the opposing side of the intermediate layer may be considered smooth. When a surface has been intentionally roughened, it may be referred to as a roughened surface. Finally, when a surface has not been intentionally treated, it may be considered “rough.”

Therefore, by providing a smoothing method to the intermediate layer while leaving the semiconductor packaging material or printed circuit board in a rough state, the hybrid material may be placed on the intermediate layer and present a straight path for current or flux.

It will be appreciated that the formation of the intermediate layer is achieved, in at least one exemplary embodiment, by depositing an intermediate layer onto a rough semiconductor packaging material or printed circuit board material as the base layer. The intermediate layer surface in contact with the base layer is significantly rougher than the opposing side of the intermediate layer, which we call the smooth surface of the intermediate layer.

In at least one exemplary embodiment, the intermediate layer is deposited to at least a height exceeding the average surface roughness of the semiconductor packaging or printed circuit board material.

In at least one exemplary embodiment, the semiconductor packaging or printed circuit is an epoxy build-up film impregnated with fiberglass or glass beads, for example, Ajinomoto Build-up Film (ABF) or FR4 Printed Circuit board material.

In at least one exemplary embodiment, the rough surface of the intermediate layer is operably bonded to a semiconductor packaging or printed circuit board material along a roughened surface of the semiconductor packaging material or printed circuit board material.

In at least one exemplary embodiment, the naturally rough or intentionally roughened surface of the semiconductor packaging or printed circuit board material has an average roughness, Ra, of between 0.05 to 5 microns.

In at least one exemplary embodiment, there is a layer of porous insulation deposited between the intermediate layer and the hybrid material.

In at least one exemplary embodiment, the intermediate layer is a hybrid metal.

In at least one exemplary embodiment, the hybrid metal is a conductive hybrid metal.

In at least one exemplary embodiment, the conductive hybrid metal is a copper, gold, silver, nickel-phosphorous, aluminum hybrid metals, or an alloy thereof.

In at least one exemplary embodiment, the hybrid metal is a magnetic hybrid metal.

In at least one exemplary embodiment, the magnetic hybrid metal is a nickel, iron, cobalt, nickel-iron, nickel-iron-cobalt metals, or an alloy thereof.

The selection of the material for the intermediate layer depends on the purpose of the primary hybrid material: if the primary hybrid material is to conduct current, the intermediate layer should be resistant to current, for example, nickel-phosphorus, but if the primary hybrid material is to direct magnetic flux, then the intermediate layer should be resistant to magnetic flux, for example, copper or nickel-phosphorus. Basing the choice of intermediate layer on the purpose of the primary hybrid material can decrease parasitic interactions between the intermediate layer and the primary hybrid material. Using primary hybrid material for the intermediate layer further decreases parasitic interactions between the intermediate layer and the primary hybrid material.

As noted above, the intermediate layer sits on a base, and this base may be a semiconductor packaging material or printed circuit. In at least one exemplary embodiment, the base is an epoxy plastic and is roughened, for example, by sanding, grinding, or chemical processing. Sanded epoxy plastic peaks tend to rise to a height of between fifty nanometers to five microns. In at least one exemplary embodiment, the intermediate layer is deposited until its lowest surface rises to a height exceeding the average surface roughness of the base layer.

After an initial plating, the intermediate layer may be smooth enough as is due to the use of electroplating leveling techniques. However, the intermediate layer may be additionally smoothed, or reduced down, to present a level surface using techniques such as chemical mechanical polishing “CMP” or fine grinding. The intermediate layer's upper smooth surface will have an average surface roughness that is at least 2x less than the base layer's average surface roughness.

By providing a smooth surface for the primary hybrid material, the path of current or flux through the primary hybrid material is shortened compared to a crooked path while CCVD and other similar methods of deposition are enabled to create a consistent spread of the porous insulation layer. These factors work together to provide a greater realization of the benefits of the hybrid material when a mechanical bond with epoxy plastic is desired.

### BRIEF DESCRIPTION OF THE FIGURES

FIG. 1 is a perspective view of a layer stack of the present invention.

FIG. 2 is a flowchart of an exemplary method of the present invention.

FIG. 3 is a perspective view of the base layer of the present invention.

FIG. 4 is a perspective view of an intermediary layer of the present invention operably placed on a base layer, before the intermediary layer has been subjected to a smoothing process.

FIG. 5 is a perspective view of an intermediary layer of the present invention operably placed on a base layer, after the intermediary layer has been subjected to a smoothing process.

FIG. 6 is a perspective view of an intermediary layer of the present invention operably placed on a base layer, where the smoothing process has resulted in portions of the base layer extending all the way through the intermediary layer.

FIG. 7 is a perspective view of a layer stack of the present invention wherein portions of the base layer extend into the hybrid material layer.

FIG. 8 is a perspective view of an hybrid material intermediary layer of the present invention operably placed on a base layer, before the intermediary layer has been subjected to a smoothing process.

FIG. 9a is a layer stack of the present invention wherein the intermediate layer is a hybrid material.

FIG. 9b is a layer stack of the present invention wherein the intermediate layer is a hybrid material.

### DETAILED DESCRIPTION

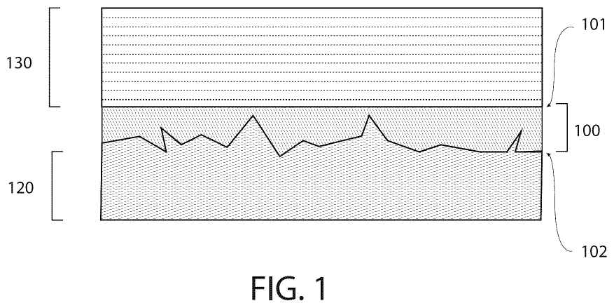

The present invention involves three main layers, although additional layers may be added: a primary hybrid material layer 130, an intermediate layer 100, and a base layer 120 as shown in FIG. 1. The layers work in concert to maximize the benefit each layer provides. The base layer will present a physical surface on which an electrical component can be formed. The intermediate layer will provide a buffer between the rough base layer and the hybrid material which has higher performance when deposited on a smooth surface.

For the purposes of this application, it will be appreciated that the ideal primary hybrid layer is a layer with straight lanes 131 between its porous insulation layers, as this provides the shortest electrical and flux pathways possible and avoids complications in insulation deposition created by the contours of rough pathways. However, due to deposition techniques, the hybrid material will follow the contours of the material that it is plated on and will follow the surface contours of the material's surface, which have some degree of roughness. This will cause the realization of the aforementioned issues. However, plating a hybrid material on a surface with reduced surface roughness would provide an effectively flat surface for the primary hybrid material, resulting in efficient lane 131 contours for the primary hybrid material 130. Therefore, a solution presented in this application is to apply an intermediate layer 100 with a smooth surface for receiving deposition and a rough lower surface for absorbing the roughness of a base layer. This provision of the intermediate layer has the added benefit of allowing for the surface roughness of the base layer 120 to be significantly increased as the intermediate layer 100 absorbs the roughness.

It will thus be appreciated that the ideal intermediate layer 100 is one that is able to absorb the surface contours of the base layer 120 and present a smooth surface for deposition of the primary hybrid material 130. However, hybrid materials deposited onto the base layer 120 will also follow the contours of the base layer 120. To solve this problem, the intermediate layer is deposited to present a smooth upper surface. The intermediary layer may be smooth enough for use after deposition, but may be further processed to increase the surface smoothness, for example, by CMP or fine grinding. This forms a smooth, typically, upper surface while the, typically, lower surface absorbs the roughness of the base layer. Although an entire surface may be smoothed or roughened, in some exemplary embodiments, only a portion of a surface is smoothed or roughened.

The smooth upper surface allows for metals, including hybrid metals, to serve as the intermediate layer. The use of metals allows for increased strength in general, as well as for chemical bonding to occur between the intermediate layer and the primary hybrid material. By using metals, an added benefit is that a porous insulation layer can be deposited on the smooth surface of the intermediate layer, and the primary hybrid material can bond to the intermediate layer through the porous boundary layer. The porous boundary layer provides an additional insulation layer to protect against eddy current formation.

It will also be appreciated that the ideal base layer is a naturally rough or intentionally roughened layer which provides mechanical benefits to the system. But, as described above, without innovation, the base layer would render the primary hybrid material less effective, as the ideal hybrid material is a material without peaks or valleys. Thus, this present application introduces an intermediate layer that absorbs the peaks and valleys of the base. Although it may seem intentionally roughing the base for improved adherence, as well as introducing an intermediate layer, would increase the size of the component incorporating this process, the component benefits from the fuller realization of the primary hybrid material layer to retain a smaller overall size when compared to a component with similar performance.

Together these three layers, the base, the intermediate layer, and the primary hybrid layer, may make up a stack of layers for a component with the significant benefits of increased strength and decreased size.

FIG. 1, as noted above, displays a cross-section view of a layer stack of an exemplary embodiment of the present invention. Here a metal forms an intermediate layer 100. This intermediate layer 100 has a smooth surface 101 and a rough surface 102. The rough surface 102 is bonded to base 120, and the smooth surface 101 is bonded to a primary hybrid material 130.

It can be seen that the individual lanes 131 of the primary hybrid material 130 form straight pathways through the length of the primary hybrid material 130. This ensures the shortest distance between the ends of lane 131. It will also be appreciated that the rough surface of the intermediate layer 100 matches the surface of the base 120, and the roughness of the surfaces creates a mechanical connection between the semiconductor base 120 and the intermediate layer 100. Therefore, it can be seen that by the use of an intermediate layer 100, the mechanical benefits of roughened semiconductor plastic base are achieved without compromising the benefits of the primary hybrid material 130.

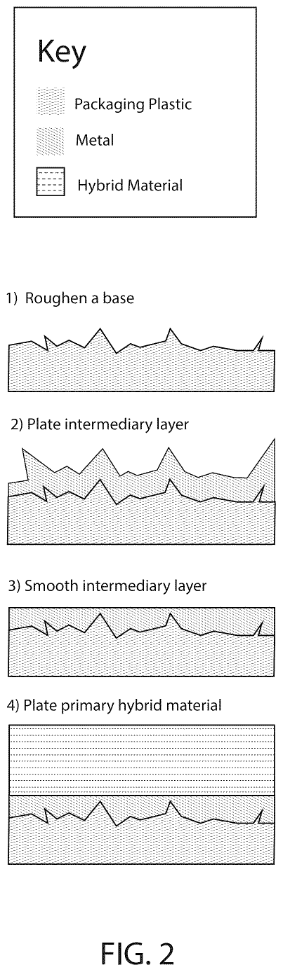

As shown in FIG. 2, to form an intermediate layer within a layer stack, a plastic is taken as a base, the plastic may be roughened, a metal is plated onto the plastic, the metal is smoothed, and the primary hybrid layer is plated onto the smooth surface of the metal. These steps are treated in detail below.

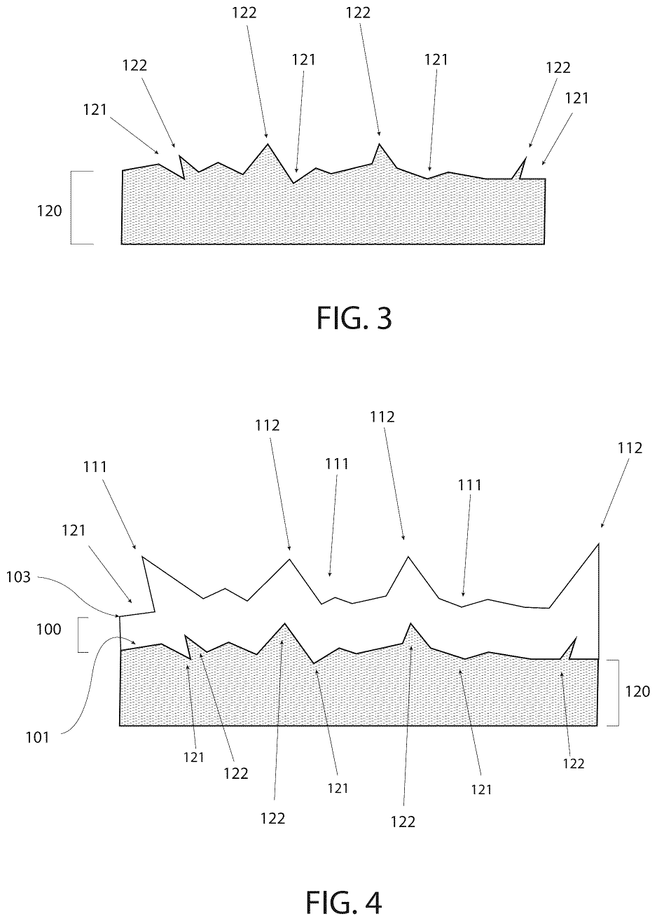

In the initial step, one may take a base 120. A rough plastic surface, as defined above, may be used as the base to receive the intermediate layer, but it has been found optimal to purposely increase the surface roughness of the plastic. The roughening process may be accomplished by sanding, which has been found to reliably create peaks 122 of fifty nanometers to five microns in height. A roughened base 120 is shown in FIG. 3, the plastic has a series of valleys 121 and peaks 122. These peaks 121 and valleys 122, in at least one exemplary embodiment, create a surface with an average surface roughness (Ra) of between fifty nanometers to five microns. These peaks and valleys will serve as a series of joints that allow for a layer formed on the plastic to interlock with the base.

The material of the base 120 is a semiconductor packaging or printed circuit board material and includes but is not limited to epoxy plastic, glass bead or fiberglass infused epoxy plastic, and various build-up films, including ABF.

A layer formed by deposition methods on the base will follow the surface lines of the base. For example, as shown in FIG. 4, an intermediate layer 100 has been plated onto the roughened surface of base 120. This intermediate layer 100 is metal and has a first rough surface 102, but does not yet have a first smooth surface 101 instead, having a second rough surface 103. The rough surface is achieved simply by depositing the metal onto the plastic, as the metal will align with the contours of the plastic to form a surface with a series of peaks 112 and valleys 111 matching the peaks 122 and valleys 121 of the plastic.

A wide variety of metals may be used to form a metal layer. In at least one exemplary embodiment, the choice of metal to be plated onto the plastic may depend on the intended use of the primary hybrid component. For example, if the primary hybrid layer is intended to conduct electricity, the intermediate layer may be a metal with high resistance to help prevent the current from traveling into the intermediate layer, for example, nickel-phosphorus. If the primary hybrid material is intended to handle magnetic flux, the intermediate layer may be formed of a metal with a high reluctance to reduce the likelihood of flux lines running through the intermediate layer. Further, when the primary hybrid material is intended to handle magnetic flux, it may be desirable for the intermediate layer to be a metal that is resistant to eddy current generation as well as flux to help reduce the eddy currents generated by magnetic forces. Some examples of metals resistant to magnetic flux are copper, aluminum, silver, gold, nickel-phosphorous, and the alloys thereof. Several examples of materials resistant to current (when compared to copper) are nickel, iron, cobalt, and the alloys thereof. These metals and their alloys may include other elements in their composition which enhance or otherwise affect their performance, and these compositions may be used herein as well.

It is preferable that the intermediate layer should be thick enough to cover the peaks 122 or the average height of the peaks of the base layer enough so that a subtractive smoothing process, for example, grinding, will still present a smooth upper surface of the intermediate layer material. The thickness, in this case, is dependent on the peak height and valley depth of the base layer. In at least one exemplary embodiment, the valleys should be overfilled to a height exceeding the average peak depth so that when the intermediate layer surface is smoothed, there is no valley remaining or cavity created.

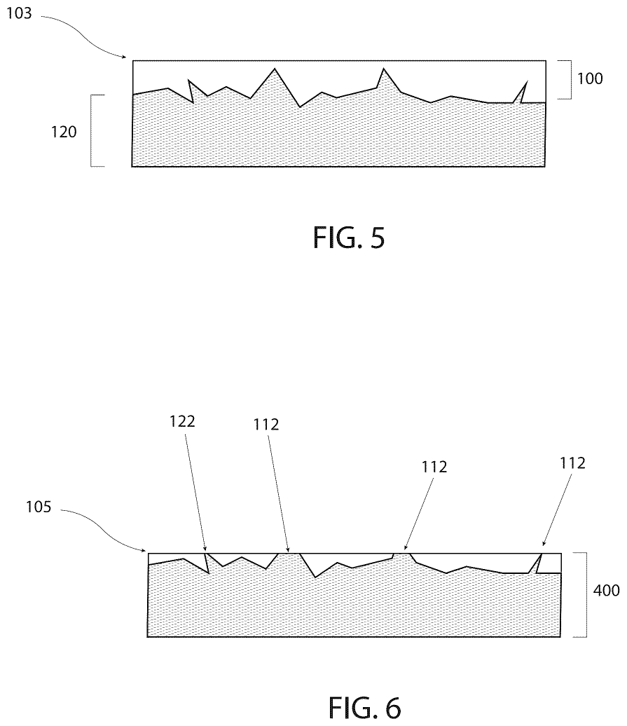

Once the metal is selected for the intermediate layer and deposited onto the base layer, as shown in FIG. 3, it will be appreciated that the intermediate layer will have a rough upper surface not suitable for receiving a primary hybrid material layer. Therefore, this surface of the intermediate layer is subject to a smoothing process. In at least one exemplary embodiment, the smoothing process results in a surface 103 with an average roughness of fewer than fifty nanometers. FIG. 5 shows a base layer 120 and an intermediate layer 100 where the upper surface has been ground down to form a smooth surface 103 of the intermediate layer 100.

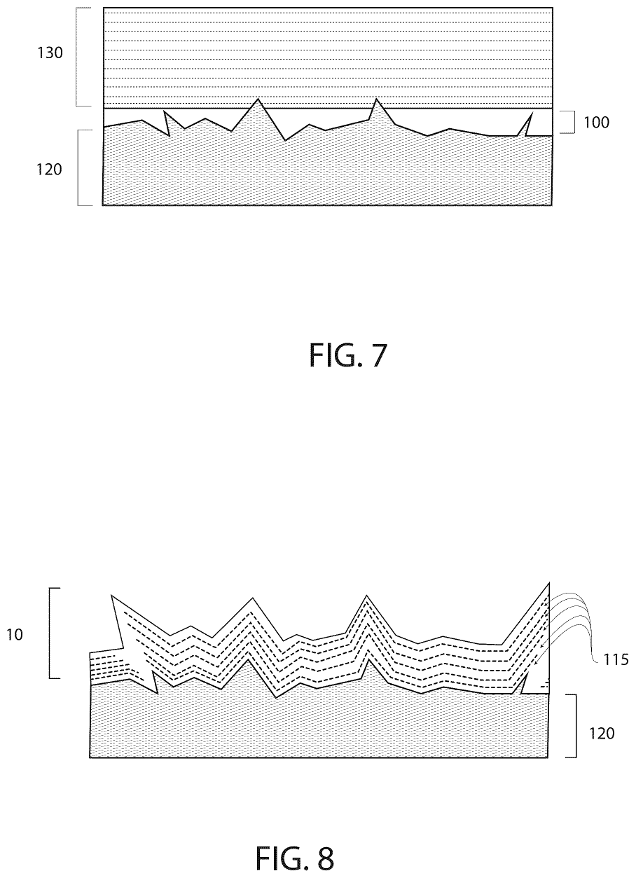

However, in not all cases will the intermediate layer fully cover the peaks of the base layer, therefore, in at least one exemplary embodiment, the intermediate layer does not fully encapsulate the peaks 122 of the base layer 120. The result is that, when smoothed by subtraction, the upper surface 105 of stack 400 will consist of the intermediate layer 100 and base layer 120, as shown in FIG. 6. This will still present a smooth surface for the primary hybrid material; however, it reduces the strength of the mechanical connections by reducing the peak height. It will also be appreciated, in at least one exemplary embodiment, and as may happen in practice, that some portions of the peaks 122 may extend into the primary hybrid material 130 as shown in FIG. 7. If only a small portion of the peaks penetrate the hybrid material 130 the upper layers of the hybrid material 130 should remain relatively unaffected. This may happen during an additive smoothing process, where instead of grinding an excess portion of the intermediate layer, the intermediate layer is built up with the goal of presenting a flat upper surface.

Once the smooth surface 101 is formed, the primary hybrid material layer 130 may be placed. The primary hybrid material 130 may be deposited directly on the smooth surface 101 of the intermediate layer 100, as shown in FIG. 1. As noted above, the intermediate layer can be chosen according to the desired purpose of the primary hybrid material particular useful combinations include a copper intermediate layer for a nickel-iron primary hybrid material, a nickel-phosphorus intermediate layer for a nickel-iron primary hybrid material, and a nickel-phosphorus intermediate layer for a copper primary hybrid material as these combinations help prevent unwanted current or magnetic flux into the base layer. However, it will be appreciated that many combinations exist and may be useful.

Particular useful combinations involve the use of hybrid materials, including nickel-phosphorus, a hybrid conductive metal, or hybrid magnetic metals. Thus hybrid metals can have primary metal compositions of copper, silver, gold, aluminum, nickel, iron, cobalt, and alloys thereof, for example. These hybrid materials can be used to create the intermediate layer 100.

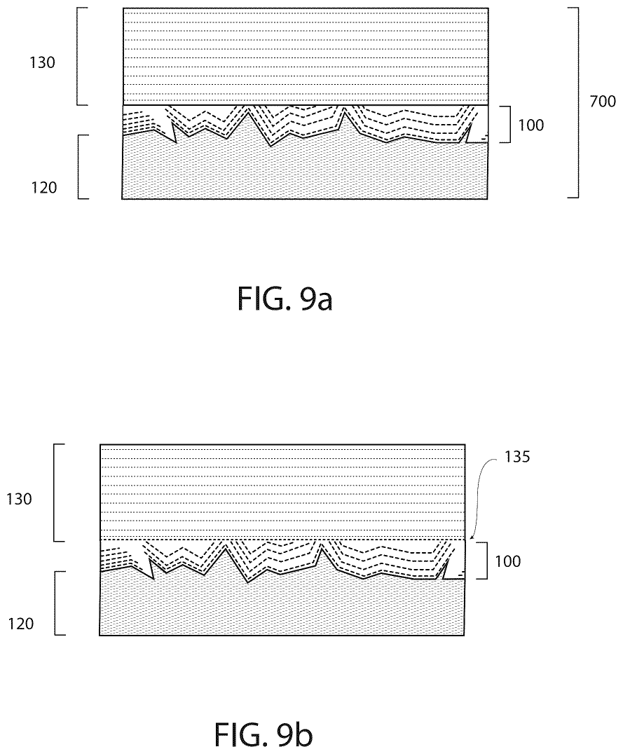

FIG. 8 shows a hybrid material forming the intermediate layer 100 after it has been placed onto the base layer 120. The use of a hybrid material, as shown here, would create the hybrid material performance issues previously mentioned, and insulation dead zones 108, where there is no insulation layering, can be seen. as well as significantly distorted current lanes 115. However, if the hybrid layer material is chosen to help prevent current, flux, or both from utilizing the intermediate layer 100, the contoured porous insulation lanes 115 will further reduce the ability of current, flux, or both to utilize the intermediate layer 100. The result is a stack 700 shown in FIG. 9a, with a base layer 120, an intermediate layer 100 of hybrid material, and a primary hybrid material layer 130. This significantly helps to remove parasitic current or flux interactions with the intermediate layer 100.

To further separate the intermediate layer 100 from the primary hybrid material 130, a layer of porous insulation 135 may be placed between the intermediate layer 100 and the primary hybrid material 130, as shown in FIG. 9b. Due to the voids of the porous insulation layer, the intermediate layer and the primary hybrid material layer may bond with each other through the insulation and thus keep a strong bond.

One of the ordinary skills in the art will appreciate that multiple layers can be added to the three main layers of a base 120, intermediate layer 100, and hybrid material 120. It may be useful, in some circumstances, to add a true laminate insulation layer between the intermediate layer and the hybrid material. It may also be useful to add metals into the layer stack to help control other performance factors of the stack, for example, controlling for consistency over temperature by adding layers that control for thermal expansion. The exact layering, if additional layers are added, will depend on the purpose, cost, and operating conditions of the component incorporating the present invention.

However, from the above, it will be appreciated that the three main layers: a primary hybrid material layer 130, an intermediate layer 100, and a base layer 120 as shown in FIG. 1 work in concert to maximize the benefit each layer provides. As noted, the base layer provides a strong base against delamination. The intermediate layer works to allow the base layer to increase the mechanical strength while allowing a primary hybrid material layer to operate at fuller efficiency; and the efficient primary hybrid material layer then allows for the overall layer stack size to remain small.

The drawings and figures show multiple embodiments and are intended to be descriptive of particular embodiments but not limited with regard to the scope or number, or style of the embodiments of the invention. The invention may incorporate a myriad of styles and particular embodiments. All figures are prototypes and rough drawings: the final products may be more refined by one of skill in the art. Nothing should be construed as critical or essential unless explicitly described as such. Also, the articles “a” and “an” may be understood as “one or more.” Where only one item is intended, the term “one” or other similar language is used. Also, the terms “has,” “have,” “having,” or the like are intended to be open-ended terms.

1. An intermediate layer, comprising: a first rough surface and a first smooth surface, the first rough surface being operably bonded to a base layer, and the first smooth surface operably bonded to a primary hybrid material layer, the hybrid material layer having a layer roughness equivalent to the first smooth surface.

2. The intermediate layer of claim 1, further comprising the first smooth surface being operably bonded to the primary hybrid material layer through a porous insulation layer.

3. The intermediate layer of claim 1, wherein the base layer is an epoxy plastic impregnated with glass beads or fiberglass.

4. The intermediate layer of claim 1, further comprising the first smooth surface being operably bonded to the base layer along a roughened surface of the base layer.

5. The intermediate layer of claim 4, wherein the surface of the base layer has an average roughness, Ra, of between 0.05 to 5 microns.

6. The intermediate layer of claim 1, wherein the metal is a hybrid metal.

7. The intermediate layer of claim 6, wherein the hybrid metal is a conductive hybrid metal.

8. The intermediate layer of claim 7, wherein the conductive hybrid metal is a copper, gold, silver, aluminum, nickel-phosphorous hybrid metals, or an alloy thereof.

9. The intermediate layer of claim 6, wherein the hybrid metal is a magnetic hybrid metal.

10. The intermediate layer of claim 9, wherein the magnetic hybrid metal is a nickel, iron, cobalt, nickel-iron, nickel-iron-cobalt metals, or an alloy thereof.

11. A method of forming an intermediate layer, comprising; taking a take a base layer having a surface with an average surface roughness; forming a first rough surface of an intermediate layer by operably depositing and bonding the intermediate layer onto the surface of the base layer; forming a first smooth surface of the intermediate layer by reducing a surface roughness of a non-bonded surface of the intermediate layer; and depositing a primary hybrid material layer onto the first smooth surface.

12. The method of claim 11, wherein the intermediate layer is deposited to at least a height exceeding the average surface roughness of the base layer.

13. The method of claim 11, further comprising depositing a porous insulation layer between the intermediate layer and the primary hybrid material layer.

14. The method of claim 11, wherein the base layer is an epoxy plastic impregnated with glass beads or fiberglass.

15. The method of claim 11, further comprising the first rough surface of the intermediate layer being operably bonded to a base layer along a roughened surface of the base layer.

16. The method of claim 15, wherein the roughened surface of the base layer has an average peak height between 0.05 to 5 microns.

17. The method of claim 16, wherein the intermediate layer is a hybrid metal.

18. The method of claim 17, wherein the intermediate layer is a conductive hybrid metal.

19. The method of claim 18, wherein the conductive hybrid metal is a copper, gold, silver, nickel-phosphorus, aluminum hybrid metals, or an alloy thereof.

20. The method of claim 17, wherein the hybrid metal is a magnetic hybrid metal.

21. The method of claim 20, wherein the magnetic hybrid metal is a nickel, iron, cobalt, nickel-iron, nickel-iron-cobalt metals, or an alloy thereof.
